(19) United States
(12) Patent Application Publication
(10) Pub. No.: US 2025/0370076 A1
(43) Pub. Date: Dec. 4, 2025

(54) SYSTEMS AND METHODS FOR MAGNETIC RESONANCE IMAGING SCANNING

(71) Applicant: SHANGHAI UNITED IMAGING HEALTHCARE CO., LTD., Shanghai (CN)

(72) Inventors: Hongqin ZHU, Shanghai (CN); Chunyu WANG, Shanghai (CN); Shuheng ZHANG, Shanghai (CN); Fuyi FANG, Shanghai (CN)

(73) Assignee: SHANGHAI UNITED IMAGING HEALTHCARE CO., LTD., Shanghai (CN)

(21) Appl. No.: 19/209,747

(22) Filed: May 15, 2025

(30) Foreign Application Priority Data
May 31, 2024 (CN) 202410708012.3

(51) Int. Cl. G01R 33/48; G01R 33/341; G01R 33/54

(52) U.S. Cl. CPC G01R 33/4828; G01R 33/341; G01R 33/546

(57) ABSTRACT

A Magnetic Resonance Imaging (MRI) scan method and an MRI system are provided in the present disclosure. The method may include generating a first hydrogen nucleus image of an object using a Radio Frequency (RF) coil of the MRI system, and further include identifying at least one coil identification of at least one multi-nucleus coil in the first hydrogen nucleus image. The at least one multi-nucleus oil is placed on body surface of the object. The method may also include determining an imaging range of the at least one multi-nucleus coil based on the at least one identified coil identification in the first hydrogen nucleus image, and determining whether to generate a multi-nucleus image of the object using the at least one multi-nucleus phased-array coil based on the imaging range of the at least one multi-nucleus oil and a Region Of Interest (ROI) on the first hydrogen nucleus image.

### CROSS-REFERENCE TO RELATED APPLICATION

This application claims the benefit of priority to Chinese Application No. 202410708012.3 filed May 31, 2024. The entire contents of the above-referenced application are expressly incorporated herein by reference.

### TECHNICAL FIELD

This application relates to the field of medical imaging technology, particularly regarding scanning methods, magnetic resonance imaging equipment and computer equipment for positioning multi-nucleus coil in hydrogen nucleus image.

### BACKGROUND

With the development of Magnetic Resonance Imaging (MRI) technology, MRI technology has expanded from hydrogen nucleus imaging to multi-nucleus imaging for better quantitative analysis and qualitative analysis of specific diseases and functions of human organs.

In current multi-nucleus scanning workflows, multiple transceiver coils each corresponding to a separate nuclide are used for scanning multi-nucleus of an imaging object (e.g., a patient). When performing the multi-nucleus imaging of the object, a hydrogen nucleus image may first be generated via scanning the object as well as a multi-nucleus coil placed within an imaging range of the transceiver coil. However, the multi-nucleus coil usually cannot be easily identified in the hydrogen nucleus image, and thus the hydrogen nucleus image cannot be effectively used to locate the multi-nucleus coils as well as an imaging range of the multi-nucleus coil. In most situations, medical staffs need to physically adjust the position of the object relative to the multi-nucleus coils in the MRI system to ensure that a Region Of Interest (ROI) of the object is within the imaging range of the multi-nucleus coil.

Embodiments of the disclosure address the above drawbacks and provide an MRI scan method for positioning a multi-nucleus coil in the hydrogen nucleus image.

### SUMMARY

Embodiments of the disclosure provide an MRI scan method for positioning a multi-nucleus coil in a hydrogen nucleus image.

An MRI scan method is provided in the present disclosure. An exemplary MRI scan method may include generating a first hydrogen nucleus image of an object using a Radio Frequency (RF) coil of the MRI system. The exemplary MRI scan method may further include identifying at least one coil identification of at least one multi-nucleus coil in the first hydrogen nucleus image. The at least one multi-nucleus coil is placed on body surface of the object. The exemplary MRI scan method may also include determining an imaging range of the at least one multi-nucleus coil based on the at least one identified coil identification in the first hydrogen nucleus image. The exemplary MRI scan method may additionally include determining whether to generate a multi-nucleus image of the object using the at least one multi-nucleus coil based on the imaging range of the at least one multi-nucleus coil and a ROI on the first hydrogen nucleus image.

An MRI system is provided in the present disclosure. An exemplary MRI system may include a scanner, at least one multi-nucleus coil, and a controller. The scanner may include an RF coil. The scanner may have an imaging area to accommodate an object. The at least one multi-nucleus coil may be placed on body surface of the object. The controller may be configured to control the RF coil to scan the object to generate a first hydrogen nucleus image of the object. The controller may be further configured to identify at least one coil identification of the at least one multi-nucleus coil in the first hydrogen nucleus image. The controller may be also configured to determine an imaging range of the at least one multi-nucleus coil based on the at least one identified coil identification in the first hydrogen nucleus image. The controller may be additionally configured to determine whether to generate a multi-nucleus image of the object using the at least one multi-nucleus coil based on the imaging range of the at least one multi-nucleus coil and a ROI on the first hydrogen nucleus image.

### BRIEF DESCRIPTION OF DRAWINGS

In the drawings that are not necessarily drawn to scale, similar reference numerals may describe similar components in different views. Similar reference numerals with letter suffixes or different letter suffixes may indicate different examples of similar components. The drawings generally show various embodiments by way of examples and not limitations, and together with the description and claims, are used to explain the disclosed embodiments. Such embodiments are illustrative and are not intended to be exhaustive or exclusive embodiments of the method, system, or non-transitory computer-readable medium having instructions for implementing the method thereon.

FIG. 1 illustrates a work environment of an exemplary MRI scan method, according to embodiments of the present disclosure.

FIG. 2 is a schematic diagram showing an exemplary computer device, according to embodiments of the present disclosure.

FIG. 3 is a flowchart of an exemplary MRI scan method, according to embodiments of the present disclosure.

FIG. 4 is a flowchart of another exemplary MRI scan method, according to embodiments of the present disclosure.

FIG. 5 is a flowchart of yet another exemplary MRI scan method, according to embodiments of the present disclosure.

FIG. 6 is a flowchart of yet another exemplary MRI scan method, according to embodiments of the present disclosure.

FIG. 7a-7f each is a schematic diagram showing a hydrogen nucleus image of a scanning section, according to embodiments of the present disclosure.

FIG. 8 is a flowchart of yet another exemplary MRI scan method, according to embodiments of the present disclosure.

FIG. 9 is a schematic diagram showing an exemplary scanning device, according to embodiments of the present disclosure.

### DETAILED DESCRIPTION

Reference will now be made in detail to the exemplary embodiments, examples of which are illustrated in the accompanying drawings.

Ordinal terms such as “first,” “second,” “third” and so on are used only for identifying different features in the exemplary embodiments. They should not be understood as indicating or implying relative importance of those features. The order of features described carries no significance unless expressly described in this disclosure. In addition, the use of ordinal terms does not suggest the feature is limited to one. That is, a feature referred to using “first,” “second,” can include one or more such features. Throughout the description of this disclosure, “multiple” means at least two, such as two, three, etc., unless otherwise specified.

In describing the methods, it is contemplated that the various steps are not necessarily executed in the exact order shown in the drawings. The steps can be performed in any technically feasible order different from the order shown in the drawings.

With the development of imaging technology in the field of medical imaging, MRI technology has expanded from the hydrogen nucleus imaging to multi-nucleus imaging such as ¹³C, ¹⁹F, ²³Na, etc., for performing quantitative or qualitative analysis on certain diseases or functions of certain human organs. In current multi-nucleus scanning workflow, multi-nucleus imaging uses a separate integrated transceiver coil (e.g., multi-nucleus coil) for imaging the corresponding nuclide such as ¹³C, ¹⁹F, ²³Na, etc. A multi-nucleus coil is designed to transmit and receive RF signals for multiple different types of atomic nuclei, each with its own unique Larmor frequency. When performing multi-nucleus scanning, a hydrogen nucleus image is usually used for positioning the multi-nucleus coil relative to the ROI of the object, and then the multi-nucleus coil (e.g., multi-nucleus phased-array coil) is used for imaging the object. However, due to different imaging results corresponding to different types of atomic nuclei, location information of the multi-nucleus coil is difficultly identified in the hydrogen nucleus image, and thus the hydrogen nucleus image of the multi-nucleus coil is not reliable resource for positioning the multi-nucleus coil relative to the ROI of the object.

Particularly, when the multi-nucleus coil corresponding to a nuclide (e.g., F nuclide, Na nuclide, or C nuclide) that can only produce spectra, the multi-nucleus coil cannot effectively provide a positioning reference in the hydrogen nucleus image. The medical staff thereby cannot determine, according to hydrogen nucleus image, whether the ROI of the object is within the imaging range of the multi-nucleus coil till the medical staff operate the MRI system to physically generate a multi-nucleus image of the object. If the obtained multi-nucleus image does not show the entire ROI (e.g., only a part of the ROI is within the imaging range of the multi-nucleus coil), the medical staff needs to move out the patient table carrying the object from the scanning area, adjust the position of the patient table or the imaging object on the patient table, and then move to the patient table into a specified position of the scanning area for rescanning. The medical staff may further adjust the position of the multi-nucleus coil relative to the object. These operations may be repeated by the medical staff after each multi-nucleus scanning until an ideal multi-nucleus image (e.g., the entire ROI is shown in the multi-nucleus image) is obtained. The above discussed conventional MRI scan method for performing multi-nucleus coil imaging may be time-consuming and complicated operations.

In some embodiments of the present disclosure, an MRI scan method performed by an MRI system are provided. The MRI system may include an RF coil and one or more multi-nucleus coils. In some embodiments, the multi-nucleus coil is placed on the body surface of the object. The MRI scan method may include using the RF coil to scan the hydrogen nucleus of an imaging object and generating at least one hydrogen nucleus image of the object. The multi-nucleus coil is placed within the imaging range of the RF coil. For example, the imaging range of the RF coil is large enough to include the entire multi-nucleus coil in the hydrogen nucleus image. The hydrogen nucleus image may further include one or more positioning information of the multi-nucleus coil (e.g., coil identifications of the multi-nucleus coil). The coil identification may be materials physically embedded inside or outside of the multi-nucleus coil for positioning or visualizing a location of the multi-nucleus coil in the hydrogen nucleus image. The MRI scan method may further include determining an imaging range of the multi-nucleus coil based on the positioning information (e.g., the coil identifications) of the multi-nucleus coil displayed in the hydrogen nucleus image. The MRI scan method may also include performing MRI scanning of the multi-nucleus of the object using the multi-nucleus coil based on the determined imaging range of the multi-nucleus coil and generating a multi-nucleus image of the object.

In some embodiments, after the RF coil is used to scan the imaging object, the MRI system may generate the hydrogen nucleus image and identify the coil identification of the multi-nucleus coil displaying in the hydrogen nucleus image. The position of the multi-nucleus coil in the hydrogen nucleus image thereby is located based on the identified coil identification of the multi-nucleus coil. In this way, the medical staff may be able to confirm that the position of the multi-nucleus coil relative to the object is good for generating an effective multi-nucleus image including the entire ROI of the object. Compared with the prior art, the MRI scan method for verifying the position of the multi-nucleus coil relative to the object is easy to implement and may reduce extra manpower and material resources. The MRI scan method may reduce time of obtaining an effective multi-nucleus image, which increases practicality and reliability of the MRI system disclosed in this application.

In some embodiments, the present disclosure may provide the MRI scan method to identify at least one positioning reference (e.g. coil identification) of at least one multi-nucleus coil (e.g., multi-nucleus coil) in the generated hydrogen nucleus image of the object and determine whether to generate a multi-nucleus image of the object based on the at least one coil identification of the multi-nucleus coil identified in the hydrogen nucleus image.

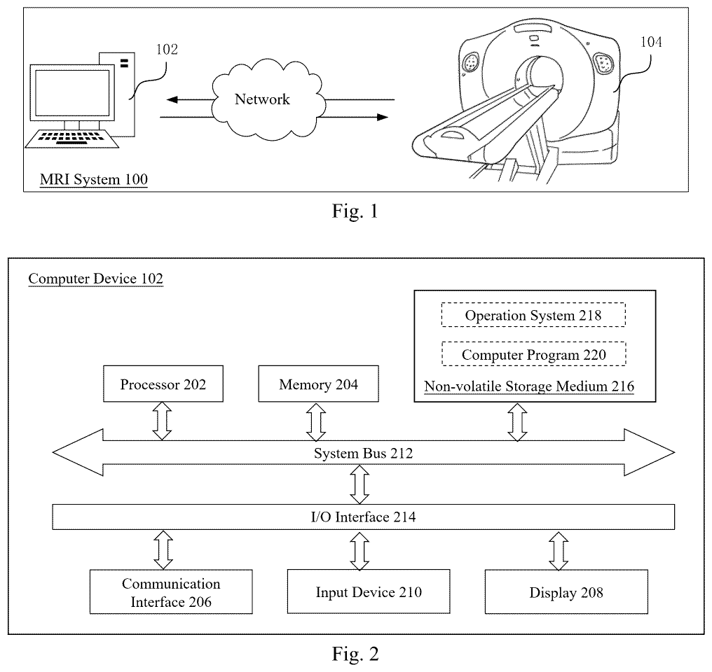

FIG. 1 illustrates a work environment of an exemplary MRI scan method, according to some embodiments of the present disclosure. For example, the MRI scan method provided in the present disclosure may be performed by an MRI system 100 as shown in FIG. 1. MRI system 100 may include a computer device 102 and a magnetic resonance device 104. In some embodiments, computer device 102 may communicate with magnetic resonance device 104 via a network. Magnetic resonance device 104 may perform an object scanning, obtain magnetic resonance signals, and transmit the magnetic resonance signals to computer device 102 via the network. After receiving the magnetic resonance signals, computer device 102 may be configured to perform image reconstruction based on the magnetic resonance signals and generate a magnetic resonance image (e.g., hydrogen nucleus image or multi-nucleus image) of the object. Computer device 102 may be, but is not limited to, an industrial computer, a notebook computer, a tablet computer, an embedded device, etc.

In some embodiments, magnetic resonance device 104 may include a magnet unit, a gradient coil unit, a RF coil unit, an RF driver, a gradient driver, and a data acquisition unit.

In some embodiments, the magnet unit may include a superconducting magnet. The magnet unit may generate a static magnetic field (B0) in an imaging space formed by an opening for accommodating the imaging object (e.g., a patient). In some embodiments, the magnet unit may form a static magnetic field extending in the direction of the body axis of the imaging object placed on the patient table.

In some embodiments, the gradient coil unit forms a gradient magnetic field in the imaging space where the static magnetic field has been formed, thereby applying or adding spatial position information to a magnetic resonance signal received by the RF coil unit. For example, the gradient coil unit may include three system settings respectively corresponding to three axis directions (e.g., z direction, x direction, and y direction) that are perpendicular to each other.

In some embodiments, magnetic resonance device 104 may emit gradient pulses in a way that a gradient magnetic field is generated in each frequency encoding direction, phase encoding direction and scanning section direction according to the imaging sequence. The gradient coil unit may apply a gradient magnetic field in a scanning section direction of the imaging object and selects the scanning section of the imaging object excited by an RF pulse emitted by the RF coil unit. The gradient coil unit may apply a gradient magnetic field in the phase-encoding direction of the imaging object, and phase-encode a magnetic resonance signal from the scanning section excited by the RF pulse. The gradient coil unit may also apply a gradient magnetic field in the frequency-encoding direction of the imaging object, and frequency-encode a magnetic resonance signal from the scanning section excited by the RF pulse.

In some embodiments, the RF coil unit may include an RF coil. The RF coil may be a volume coil or a body coil. The volume coil (e.g., radio frequency transmitting coil) may be a birdcage coil or a degenerate birdcage coil and set to surround an imaging area of the imaging object. In some alternative embodiments, the volume coil may also have a receiving function, which may receive a magnetic resonance signal generated based on the spinning of the excited hydrogen nucleus of the imaging object. In some embodiments, the RF coil may be a hydrogen nucleus coil, configured to acquire magnetic resonance signals of hydrogen nucleus of the imaging object. In some embodiments, the receiving coil may be a multi-nucleus coil (e.g., multi-nucleus phased-array coil) placed on the body surface of the imaging object, configured to acquire multi-nucleus magnetic resonance information of the imaging object.

In some embodiments, the RF driver may drive the RF coil to produce an RF pulse (e.g., excitation pulse) into the imaging space, thereby generating a high-frequency magnetic field in the imaging space.

In some embodiments, the gradient driver may apply a gradient pulse to the gradient coil unit according to a control signal output from an operation console of magnetic resonance device 104 operated by a user of magnetic resonance device 104 to drive the gradient coil unit, thereby generating a gradient magnetic field in the imaging space along with the static magnetic field (e.g., the high-frequency magnetic field).

In some embodiments, the data acquisition unit may acquire a magnetic resonance signal corresponding to the multi-nucleus of the imaging object received by the multi-nucleus coil or a magnetic resonance signal corresponding to the hydrogen nucleus of the object received by the RF coil based on a control signal output from the operation console of magnetic resonance device 104 operated by the user. The data acquisition unit may use an A/D converter to convert the magnetic resonance signal (e.g., analog signal) into a digital signal and output the digital signal to computer device 102 for further processing.

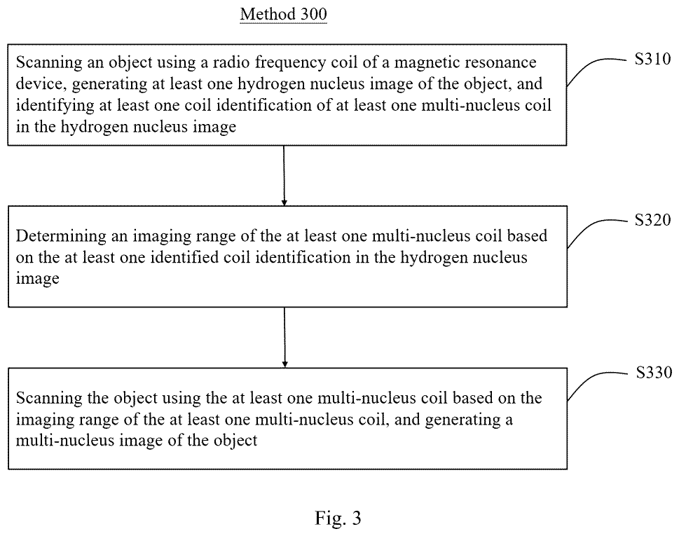

FIG. 2 illustrates an internal structure diagram of computer device 102 of FIG. 1. In some embodiments, computer device 102 may include a processor 202, a memory 204, a communication interface 206, a display 208, or an input device 210 connected through a system bus 212 and an I/O interface 214. In some embodiments, processor 202 provides computing and control capabilities. In some embodiments, memory 204 includes non-volatile storage medium 216 (e.g., non-transitory computer readable storage medium) or an internal memory (not shown in FIG. 2). In some embodiments, non-volatile storage medium 216 may store an operating system 218 or a computer program 220. In some embodiments, the internal memory provides an environment for executing operating system 218 or computer program 220 stored in non-volatile storage medium 216. In some embodiments, communication interface 206 is used for wired or wireless communication with external terminals or users (e.g., medical staff members) of MRI system 100. For example, the wireless mode may be implemented through WIFI, mobile cellular network, Near Field Communication (NFC) or other technologies. In some embodiments, computer program 220 may implement the MRI scan method when it is executed by processor 202. In some embodiments, display 208 may be a liquid crystal display or an electronic ink display including a display interface. Input device 210 may be a touch layer covered on display 208, or may be a button, a trackball, or a touch pad provided on a shell of computer device 102. In some alternative embodiments, input device 210 may be an external keyboard, a trackpad, a mouse, etc.

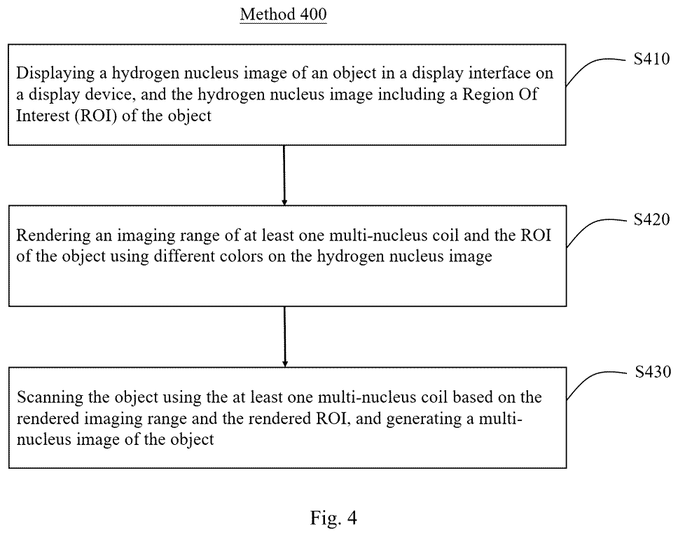

FIG. 3 shows a flowchart of an exemplary MRI scan method 300 (referred to as “method 300” hereafter). In some embodiments, method 300 may be implemented by computer device 102 along with magnetic resonance device 104 of FIG. 1. Method 300 may include steps S310-S330 as described below. It is contemplated that some of the steps may be optional to perform the disclosure provided herein. Further, some of the steps may be performed simultaneously, or in a different order than shown in FIG. 3.

In step S310, MRI system 100 (e.g., processor 202 of computer device 102) may control an RF coil of magnetic resonance device 104 to scan the object and generate at least one hydrogen nucleus image of the object. MRI system 100 may further identify the position of at least one multi-nucleus coil in the hydrogen nucleus image based on at least one coil identification of the at least one multi-nucleus coil displayed in the hydrogen nucleus image. Consistent with some embodiments, the at least one multi-nucleus coil may be placed on the body surface of the object.

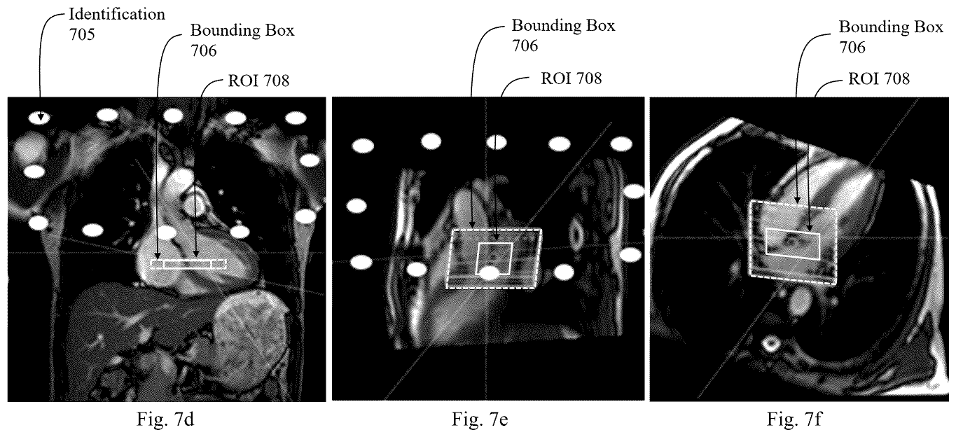

In some embodiments, multi-nucleus may refer to a combination of nuclides selected from a group including such as ²³Na, ³¹P, ¹³C, ¹²⁹Xe, ¹⁷O, ⁷Li, ¹⁹F, ³H, ²H, etc. Various metabolite information of the human body can be obtained using multi-nucleus imaging. Consistent with some embodiments, at least one coil identification is embedded with the multi-nucleus coil for positioning purposes in the hydrogen nucleus image, and thereby the at least one coil identification of the multi-nucleus coil can be displayed in the hydrogen nucleus image (e.g., white solid ovals shown in FIGS. 7a-7e). For example, the coil identification may be placed on the surface of the multi-nucleus coil or embedded inside the multi-nucleus coil. Multiple coil identifications may be evenly distributed or randomly distributed on the surface of the multi-nucleus coil or inside the multi-nucleus coil. The shape of the coil identification may be circular, oval, or any regular or irregular shapes. The coil identification may be made of materials such as vitamin E, cod liver oil, barium sulfate, fluorescent powder, bone powder, or lead powder. This disclosure does not limit the position or distribution pattern of the coil identifications, as well as the material or the shape of the coil identifications, as long as their functions can be performed (e.g., being imaged or visualized in the hydrogen nucleus image). In some embodiments, the RF coil may be configured to acquire positioning information of the multi-nuclear coil based on the materials embedded with the multi-nucleus coil that can be visualized or displayed on the hydrogen nucleus image.

In some embodiments, before performing the hydrogen nucleus scanning of the subject (e.g., a patient), a multi-nucleus coil with one or more embedded coil identifications is placed on the body surface of the imaging subject. The magnetic resonance device (e.g., magnetic resonance device 104) uses the RF coil to scan hydrogen nucleus of the object as well as the multi-nucleus coil to obtain a hydrogen nucleus image according to a corresponding scanning protocol. During the process of hydrogen nucleus scanning of the object, the one or more coil identifications of the multi-nucleus coil may be scanned. The one or more coil identifications (e.g., identification 701 in FIG. 7a and identification 705 in FIG. 7d) are imaged in the hydrogen nucleus image, that is, the obtained hydrogen nucleus image includes the one or more coil identifications of the multi-nucleus coil. For example, the coil identifications display in white solid ovals as shown in FIGS. 7a-7e.

In step S320, an imaging range of the multi-nucleus coil may be determined based on the identified coil identifications in the hydrogen nucleus image. In some embodiments, the imaging range of the multi-nucleus coil refers to an area formed by the identified coil identifications of the multi-nucleus coil in the hydrogen nucleus image.

In some embodiments, after identifying the one or more coil identifications of the multi-nucleus coil in the hydrogen nucleus image, for each identified coil identification, a nearest neighboring coil identification is determined and connected with the identified coil identification using a curve line, in such a way, all of the coil identifications identified in the hydrogen nucleus image can be connected to form a closed loop. The area enclosed in the closed loop refers to the imaging range of the multi-nucleus coil.

In some alternative embodiments, processor 202 of MRI system 100 may apply a pre-trained determination model on the hydrogen nucleus image. The pre-trained determination model may analyze the coil identifications of the multi-nucleus coil included in the hydrogen nucleus image and output an imaging range of the multi-nucleus coil.

In step S330, MRI system 100 may scan the imaging object using the multi-nucleus coil of magnetic resonance device 104 based on the determined imaging range of the at least one multi-nucleus coil, and generate a multi-nucleus image of the imaging object.

In some embodiments, after determining the imaging range of the multi-nucleus coil, MRI system 100 may determine the position of the multi-nucleus coil and determine a ROI of the object based on the hydrogen nucleus image. According to the position of the multi-nucleus coil and the position of the ROI in the hydrogen nucleus image, MRI system 100 may determine whether the ROI is within the area formed by the coil identifications of the multi-nucleus coil. For example, when the hydrogen nucleus image is an image of the upper body of the imaging subject, the ROI may include an area of the heart of the imaging subject.

In some embodiments, after generating the hydrogen nucleus image, MRI system 100 may apply a pre-trained ROI determination model on the hydrogen nucleus image to analyze the hydrogen nucleus image and determine a ROI of the object in the hydrogen nucleus image.

In some alternative embodiments, after generating the hydrogen nucleus image, MRI system 100 may segment the hydrogen nucleus image based on a preset threshold and determine the ROI in the hydrogen nucleus image based on segment results.

In some embodiments, after MRI system 100 determines that the ROI is within the area formed by the multi-nucleus coil, MRI system 100 may obtain a multi-nucleus image by performing a multi-nucleus scanning on the imaging object using the multi-nucleus coil. Consistent with some embodiments, the multi-nucleus image is a magnetic resonance image.

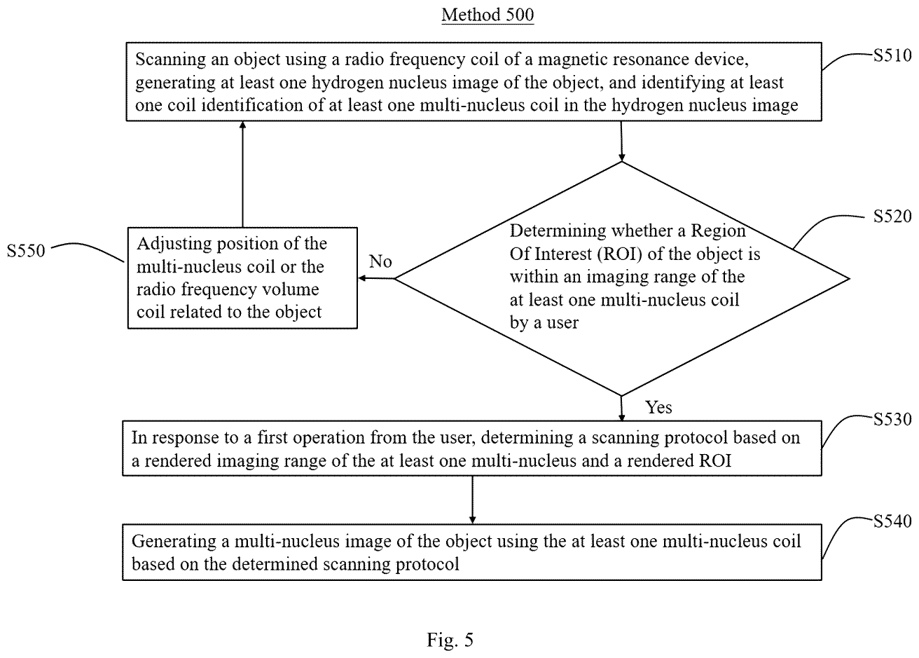

In some embodiments, as shown in FIG. 4, an MRI scan method 400 (referred to “method 400” hereafter) for obtaining a multi-nucleus image by performing a multi-nucleus scanning on an imaging object using MRI system 100 is provided. In some embodiments, method 400 may be implemented by computer device 102 along with magnetic resonance device 104 of FIG. 1. Method 400 may include steps S410-S430 as described below. It is contemplated that some of the steps may be optional to perform the disclosure provided herein. Further, certain steps may be performed simultaneously, or in a different order than shown on FIG. 4.

In step S410, a hydrogen nucleus image of the object may be displayed on a display interface (e.g., display 208 in FIG. 2). In some embodiments, the hydrogen nucleus image includes a ROI of the object. For example, after an MRI system scans an object and obtains the hydrogen nucleus image of the object, the MRI system may display the obtained hydrogen nucleus image on the display interface of the MRI system. In some embodiments, the hydrogen nucleus image may be displayed on display 208 of MRI system 100. In some embodiments, the hydrogen nucleus image may be generated by performing step S310 of method 300.

In step S420, an imaging range of at least one multi-nucleus coil of the MRI system and the ROI of the object may be rendered in different colors by a processor of the MRI system (e.g., processor 202 in FIG. 2) and displayed on the display interface of the MRI system.

In some embodiments, a first color may be used to identify the boundary of the imaging range of the multi-nucleus coil. For example, a curve line in the first color may be used to connect each coil identification displayed on the hydrogen nucleus image to form an area corresponding to the imaging range of the multi-nucleus coil. In some embodiments, a second color is used to identify the boundary of a ROI. For example, the ROI may be bound by a bounding box with outer lines in the second color. The bounding box may be illustrated in a 2-D shape or a cube, a cuboid, or other irregular 3-D shapes. For example, a parallelogram in solid line is used in FIGS. 7a-7f to illustrate the ROI and a parallelogram in dash line to illustrate the bounding box of the ROI. In some embodiments, the second color may be different than the first color. In some alternative embodiments, the second color may be the same color as the first color. Detailed color values of the first color and the second color are not limited in this present disclosure.

In some embodiments, the processor of the MRI system may obtain penetration depth of B1 field. The B1 field is an RF magnetic field that is distinct from the static magnetic field (B0) and the gradient fields, which are used for spatial encoding. The B1 field is used to tip the nuclear magnetization (the alignment of hydrogen nuclei in the body of the imaging object) and generate the MR signal. The penetration depth of the B1 field refers to the depth at which the RF field effectively interacts with the tissue of the imaging object. The penetration depth of the B1 field varies depending on frequency and material properties. In some embodiments, the processor of the MRI system may further determine a bounding box of the ROI on the hydrogen nuclear image based on the obtained penetration depth and the ROI. In other words, the ROI (e.g., ROI 704 of FIGS. 7a-7c and ROI 708 of FIGS. 7d-7f) may be bound on the hydrogen nucleus image by the bounding box (e.g., bounding box 702 of FIGS. 7a-7c and bounding box 706 of FIGS. 7d-7f). For example, the size of the bounding box, the center position of the bounding box, and the direction of the bounding box are determined. In some embodiments, the depth information of the multi-nucleus coil may be pre-determined and stored in the memory of the MRI system (e.g., memory 204).

In step S430, the MRI system may scan the object based on the rendered imaging range and the rendered ROI using the multi-nucleus coil, and generate a multi-nucleus image of the object. In some alternative embodiments, the MRI system may not render the imaging range of the multi-nucleus coil and the ROI of the object, but scan the object using the multi-nucleus coil based on the unrendered imaging range and the unrendered ROI to generate the multi-nucleus image of the object.

In some embodiments, after the MRI system renders the imaging range and the ROI and displays rendering results on the display interface, the MRI system may determine whether the whether the rendered ROI is within the rendered imaging range of the multi-nucleus coil based on the rendered ROI and the rendered imaging range of the multi-nucleus coil. For example, the MRI system may display a determination result on the display interface for the user to review. A user of the MRI system (e.g., a medical staff member) may review the rendering results to determine whether the rendered ROI is within the rendered imaging range of the multi-nucleus coil. If the user determines that the rendered ROI is within the rendered imaging range, the user may instruct the MRI system to scan the object using the multi-nucleus coil and generate the multi-nucleus image of the object. For example, the user may perform a first operation via a communication interface (e.g., communication interface 206), an input device (e.g., input device 210), or a display interface (e.g., display 208) to inform the MRI system that the rendered ROI is within the rendered imaging range. In response to the first operation, the MRI system may perform a multi-nucleus scanning on the object using the multi-nucleus coil and generate a multi-nucleus image of the object. In some embodiments, the first operation may be a confirmation operation used to indicate that the ROI is within the imaging range of the multi-nucleus coil.

In some embodiments, the first operation may be a click operation or a drag operation performing onto the rendered imaging range or the rendered ROI via the display interface, the input device, or the communication interface of the MRI system. In some embodiments, a confirmation control (e.g., virtual button) may be displayed on the display interface or the communication interface. In response to the first operation performed on the confirmation control from the user, the MRI system may perform the multi-nucleus scanning on the object using the multi-nucleus coil to generate the multi-nucleus image of the object. In such human-computer interaction, the user may be able to quickly verify whether the rendered ROI is within the rendered imaging range, thereby reducing the quantity of scanning the object and improving the quality of the multi-nucleus image of the object.

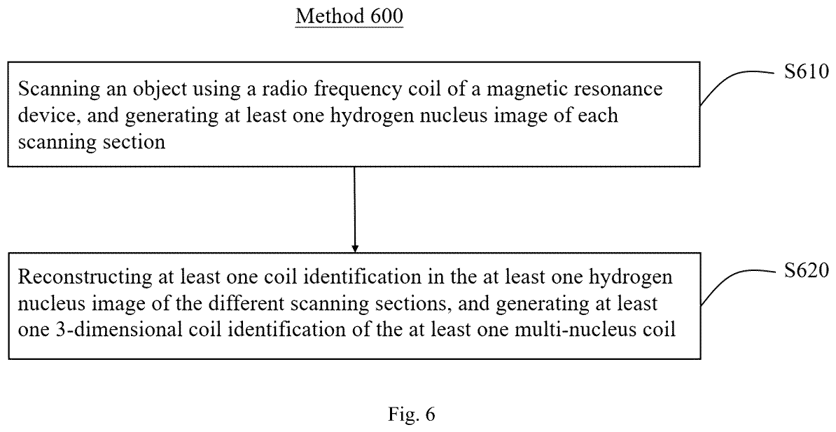

FIG. 5 is a flowchart showing an MRI scan method 500 (referred as “method 500” hereafter), according to some embodiments of the present disclosure. Method 500 may be performed by computer device 102 along with magnetic resonance device 104 of FIG. 1. Method 500 may include steps S510-S550 as described below. It is contemplated that some of the steps may be optional to perform the disclosure provided herein. Further, some of the steps may be performed simultaneously, or in a different order than shown in FIG. 5.

In step S510, computer device 102 of MRI system 100 (e.g., processor 202) may control the RF coil of magnetic resonance device 104 to scan the object and generate at least one hydrogen nucleus image of the object. Consistent with some embodiments, processor 202 may further identify at least one coil identification of at least one multi-nucleus coil in the generated hydrogen nucleus image. Processor 202 may also determine the imaging range of the multi-nucleus coil based on the identified coil identification on the hydrogen nucleus image. Consistent with some embodiments, processor 202 may additionally determine the ROI of the object based on depth information of the multi-nucleus coil. Processor 202 may further render the imaging range and the ROI on the hydrogen nucleus image.

In step S520, the user of MRI system 100 may determine whether the ROI of the object is within the imaging range of the multi-nucleus coil, and display the determination to the user for review. Consistent with some embodiments, the user may review the rendered imaging range and the ROI displayed on the display interface to determine whether the rendered ROI is within the rendered imaging range.

Consistent with some embodiments, if the user determines that the rendered ROI is within the rendered imaging range, the user may input a first operation into the MRI system for confirming that the rendered ROI is within the rendered imaging range.

In step S530, in response to the first operation from the user, the MRI system may further determine a scanning protocol corresponding to the multi-nucleus coil based on the rendered imaging range and the render ROI. In some embodiments, the scanning protocol of the multi-nucleus coil refers to a set of scanning parameters required for scanning multi-nucleus of the object, and the scanning protocol may include at least one setting for scanning type, body part for scanning, sampling mask, magnification ratio, resolution, or scanning speed, corresponding to the multi-nucleus coil.

In some embodiments, the user of the MRI system may preset an initial scanning protocol corresponding to the multi-nucleus coil in the MRI system. After the imaging range or the ROI is determined, the MRI system may update parameter values of the scanning protocol (e.g., position parameters) based on the determined imaging range or ROI. In some alternative embodiments, the MRI system may update the parameter values in the initial scanning protocol based on the rendered imaging range or ROI.

In step S540, after the MRI system updates the scanning protocol corresponding to the multi-nucleus coil, the MRI system may use the multi-nucleus coil to scan the object based on the updated scanning protocol and generate a multi-nucleus image of the object.

In some embodiments, if the user of the MRI determines that the rendered ROI is not within the rendered imaging range after reviewing the imaging range and the ROI rendered on the hydrogen nucleus image, the user may input a second operation into the MRI system. The second operation is used to indicate that the rendered ROI is not within the rendered imaging range (e.g., as shown in FIGS. 7d-7f). In some embodiments, the user may enter the second operation to the MRI system when a part of the rendered ROI is located out of the rendered imaging range. In some alternative embodiments, the user may enter the second operation to the MRI system when the entirety of the rendered ROI is located out of the rendered imaging range as shown in FIG. 7d.

In some embodiments, before the user enters the second operation to the MRI system, the user may adjust the position of the RF coil or the position of the multi-nucleus coil relative to the object. For example, in step S550, the user may change the position of the object relative to the RF coil by moving the patient table carrying the object relative to the RF coil. As another example, the user may adjust the position of the multi-nucleus coil relative to the object by moving the multi-nucleus coil on the body surface of the object. After adjusting the relative position between the RF coil and the object, or adjusting the relative position between the multi-nucleus coil and the object, the user may enter the second operation to inform the MRI system to generate a new hydrogen nucleus image. After receiving the second operation, the MRI system may perform step S510 again and generate the new hydrogen nucleus image for determining whether the ROI is within the imaging range of the multi-nucleus coil in the new hydrogen nucleus image. In some embodiments, after the user adjusted the position of the multi-nucleus coil or the RF coil relative to the object, the user may decide to skip generating a new hydrogen nucleus image, but instruct the MRI system to generate a multi-nucleus image of the object using the multi-nucleus coil by inputting the first operation.

In some alternative embodiments, the display interface of the MRI system may display a control of cancellation (e.g., virtual button). The second operation may refer to a clicking operation on the virtual button displayed on the display interface. In response to the second operation, the MRI system may display an information window on the display interface to remind the user to adjust the position of the RF coil or the multi-nucleus coil relative to the object. After the user adjusts the relative positions of the RF coil or the multi-nucleus coil relative to the object on the patient table, the MRI system may perform step S510 again and generate a new hydrogen nucleus image for determining whether the ROI is within the imaging range of the multi-nucleus coil in the new hydrogen nucleus image.

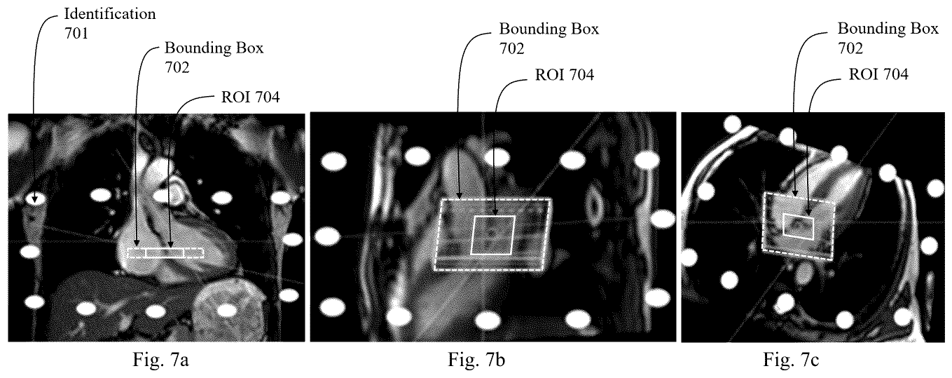

FIG. 6 is a flowchart of another exemplary MRI scan method 600 (referred as “method 600” hereafter), according to some embodiments of the present disclosure. Method 600 may include scanning an object using an RF coil of a magnetic resonance device (e.g., magnetic resonance device 104) and generating a hydrogen nucleus image of the object. Method 600 may further include identifying a coil identification of a multi-nucleus coil of the magnetic resonance device in the hydrogen nucleus image.

In step S610, the hydrogen nucleus of the object may be scanned by the magnetic resonance device of the MRI system (e.g., MRI system 100) using the RF coil of the magnetic resonance device. Consistent with some embodiments, one or more multi-nucleus coils may be placed on the body surface of the object. The multi-nucleus coil may include at least one coil identification which may be imaged in the hydrogen nucleus image. The magnetic resonance device of MRI system 100 may generate hydrogen nucleus images for each scanning section. In some embodiments, the scanning section may include coronal plane, median sagittal section, or transverse section.

For example, the magnetic resonance device (e.g., magnetic resonance device 104) may scan the hydrogen nucleus of the imaging object and obtain the hydrogen nucleus image of the imaging object in the coronal plane, the median sagittal section, and the transverse section, respectively. FIGS. 7a and 7d each shows a hydrogen nucleus image of the coronal plane, FIGS. 7b and 7e shows a hydrogen nucleus image of the median sagittal section, and FIGS. 7c and 7f each shows a hydrogen nucleus image of the transverse section. Consistent with some embodiments, a ROI in the hydrogen nucleus image may be illustrated using a parallelogram in solid line (e.g., ROI 704 of FIGS. 7a-7c and ROI 708 of FIGS. 7d-7f) on each hydrogen nucleus image. Each ROI on the hydrogen nucleus image of different sections may be bound by a bounding box. For example, FIGS. 7a-7f each shows the bounding box using a parallelogram in dash line (e.g., bounding box 702 in FIGS. 7a-7c and bounding box 706 in FIGS. 7d-7f) surrounding a parallelogram in solid line (e.g., ROI 704 of FIGS. 7a-7c and ROI 708 of FIGS. 7d-7f).

In step S620, MRI system 100 may reconstruct at least one coil identification based on the hydrogen nucleus images of different scanning sections.

For example, as shown in FIGS. 7a-7c, the hydrogen nucleus image of each scanning section may include at least one coil identification of the multi-nucleus coil (e.g., white solid ovals in FIGS. 7a-7e). After obtaining the hydrogen nucleus images of different scanning sections, MRI system may generate at least one 3-D coil identification of the multi-nucleus coil based on the coil identifications in the hydrogen nucleus images of different scanning sections. The reconstructed coil identification is three-dimensional (3-D). This present disclosure does not limit a particular method used for reconstructing the coil identifications in the hydrogen nucleus images of different scanning sections.

For example, MRI system 100 may apply a pre-trained reconstruction model on the obtained hydrogen nucleus images of different scanning sections. The reconstruction model may generate a three-dimensional hydrogen nucleus image based on the hydrogen nucleus images of different scanning sections. In some embodiments, the hydrogen nucleus image of different scanning sections each includes at least one coil identification of the multi-nucleus coil. Consistent with some embodiments, the reconstruction model may generate at least one three-dimensional coil identification of the multi-nucleus coil in the three-dimensional hydrogen nucleus image. Consistent with the present disclosure, the at least one reconstructed three-dimensional coil identification may be used in determining imaging range of the multi-nucleus coil of magnetic resonance device 104 in MRI system 100.

As another example, MRI system 100 may use Structure From Motion (SFM), Truncated Signed Distance Function (TSDF), or other methods to reconstruct the 3-D coil identification of the multi-nucleus coil based on the coil identifications displayed in the hydrogen nucleus images of different scanning sections.

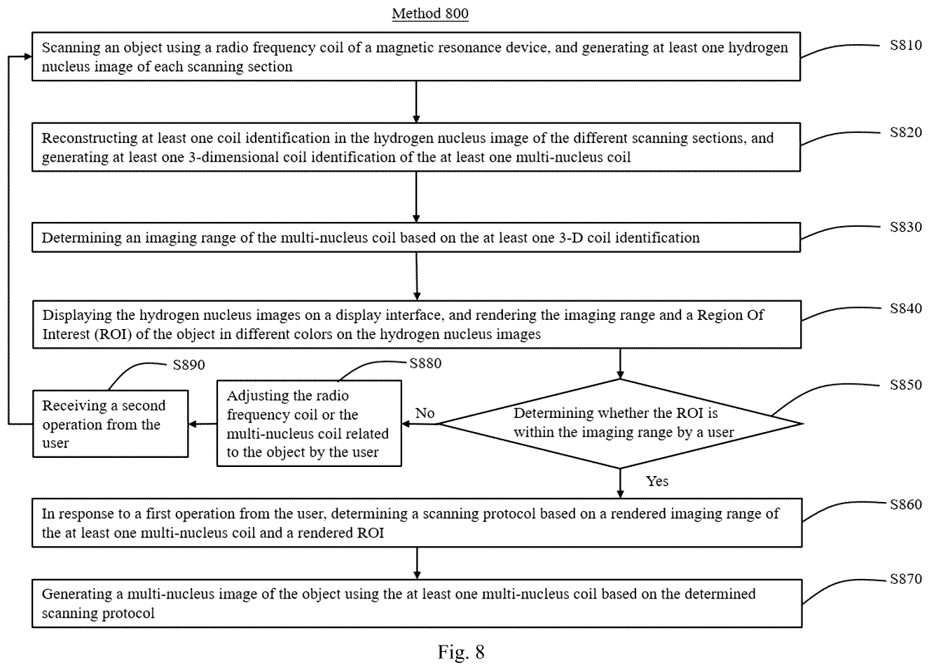

FIG. 8 shows a flowchart of another exemplary MRI scan method 800 (referred as “method 800” hereafter). In some embodiments, method 800 may be implemented by computer device 102 along with magnetic resonance device 104 of FIG. 1. Method 800 may include steps S810-S890 as described below. It is contemplated that some of the steps may be optional to perform the disclosure provided herein. Further, some of the steps may be performed simultaneously, or in a different order than shown in FIG. 8.

In step S810, the hydrogen nucleus of an object (e.g., a patient) may be scanned by an RF coil of a magnetic resonance device (e.g., magnetic resonance device 104) of an MRI system (e.g., MRI system 100). Consistent with the present disclosure, MRI system 100 may obtain hydrogen nucleus images of different scanning sections, and one or more multi-nucleus coils are placed on the body surface of the object. The multi-nucleus coil has at least one coil identification embedded on the surface of the multi-nucleus coil or inside of the multi-nucleus coil. The coil identification (e.g., identification 701 in FIG. 7a or identification 705 in FIG. 7d) may be scanned and imaged in the obtained hydrogen nucleus images of different scanning sections.

In step S820, MRI system 100 may reconstruct the coil identifications in the hydrogen nucleus images of different scanning sections and generate at least one 3-D coil identification of the multi-nucleus coil.

In step S830, MRI system 100 may determine an imaging range of the one multi-nucleus coil based on the at least one 3-D coil identification.

In step S840, MRI may display the hydrogen nucleus images of different scanning sections on a display interface (e.g., display 208). In some embodiments, MRI system may further render the hydrogen nucleus images and display the rendered hydrogen nucleus images on the display interface for a user to review. Consistent with some embodiments, the displayed image may include a rendered imaging range of the multi-nucleus coil (e.g., white solid ovals shown in FIGS. 7a-7e) and a rendered ROI of object (e.g., parallelogram in solid lines shown in FIGS. 7a-7f).

In step S850, the user (e.g., a medical staff member) of MRI system 100 reviews the rendered imaging range of the multi-nucleus coil and the rendered ROI displayed on the display interface. Consistent with some embodiments, the user may determine whether the ROI is within the imaging range of the multi-nucleus coil after reviewing the rendered hydrogen nucleus images of the different scanning sections displayed on the display interface of MRI system 100.

Consistent with the present disclosure, after the user determines that the ROI is within the imaging range of the multi-nucleus coil, the user may enter a first operation into MRI system 100 via communication interface 206, input device 210, or display 208.

In step S860, in response to the first operation, MRI system 100 may determine a scanning protocol corresponding to the multi-nucleus coil based on the rendered imaging range of the multi-nucleus coil and the rendered ROI.

In step S870, MRI system 100 may scan the object using the multi-nucleus coil based on the determined scanning protocol corresponding to the multi-nucleus coil.

In step S880, the user may adjust the position of the RF coil or the multi-nucleus coil relative to the object on the patient table after the user determines that the ROI is not within the imaging range of the multi-nucleus coil (as shown in FIGS. 7d-7e).

In step S890, MRI system 100 may receive a second operation from the user after the user adjusts the relative position between the RF coil and the object, or the relative position between the multi-nucleus coil and the object. Consistent with some embodiments, the user may perform the second operation on a control (e.g., virtual button) displayed on the communication interface 206 or display 208, or perform the second operation (e.g., a click operation or a drag operation) on the rendered hydrogen nucleus image displayed on the display interface. After receiving the second operation, MRI system 100 may perform step S810 to rescan the hydrogen nucleus of the object on the patient table using the RF coil to generate a new hydrogen nucleus image. In some embodiments, MRI system 100 may repeat steps S810-S870 to generate a new multi-nucleus image of the object. The new multi-nucleus image may include the entire ROI of the object.

Although the steps in the flowcharts in the present disclosure are shown in sequence as indicated by arrows, these steps are not necessarily executed in the order indicated by the arrows. There is no strict order restriction on the execution of these steps, and these steps can be executed in a different order. Moreover, one step may include multiple sub-steps or sub-phases. These sub-steps or sub-phases may be executed at the same time, or at different times. The execution order of these sub-steps or sub-phases may be sequential, or in turn or alternately with other steps or at least part of the sub-steps or the sub-phases in other steps.

Consistent with some embodiments, an MRI system is provided in the present disclosure. For example, the MRI system may include a scanner. The scanner may include an RF coil. The scanner has an imaging area that surrounds the object (e.g., a patient). The MRI system may further include at least one multi-nucleus coil placed on the body surface of the object. The MRI system may also include a controller. In some embodiments, the controller may be configured to control the RF coil to generate an excitation pulse. The excitation pulse is used for exciting hydrogen nucleus of the object to spin. The controller may control the RF coil to receive a first magnetic resonance signal generated based on the spinning of the hydrogen nucleus of the object. The controller may further generate a hydrogen nucleus image based on the received magnetic resonance signal and identify at least one coil identification of the multi-nucleus coil in the hydrogen nucleus image. The controller may also determine an imaging range of the multi-nucleus coil based on the identified coil identification in the hydrogen nucleus image. The controller may additionally control the multi-nucleus coil to excite multi-nucleus of the object to spin and control the multi-nucleus coil to receive a second magnetic resonance signal generated based on the spinning of the multi-nucleus of the object. The controller may reconstruct the second magnetic resonance signal generated based on the spinning of the multi-nucleus of the object and generate a multi-nucleus image based on the reconstructed magnetic resonance signal.

In some alternative embodiments, the MRI system may include a resonance device (e.g., magnetic resonance device 104) and a computer device (e.g., computer device 102). The resonance device may include a scanner and at least one multi-nucleus coil. The scanner may include a magnet unit, a gradient coil unit, an RF coil, an RF driver, a gradient driver, and a data acquisition unit. The scanner may include an imaging area that surrounds the object (e.g., a patient). The computer device may include a controller or a console, configured to control the RF coil to generate an excitation pulse or control the gradient coil to generate a gradient pulse. The excitation pulse is used for exciting hydrogen nucleus of the object to spin. The controller or console may control the RF coil to receive the first magnetic resonance signal generated based on the spinning of the hydrogen nucleus of the object. The controller or console may further generate a hydrogen nucleus image based on the received magnetic resonance signal and identify at least one coil identification of the multi-nucleus coil in the hydrogen nucleus image. The controller or console may also determine an imaging range of the multi-nucleus coil based on the identified coil identification in the hydrogen nucleus image. The controller or console may additionally control the at least one multi-nucleus coil to excite multi-nucleus of the object to spin and control the multi-nucleus coil to receive the second magnetic resonance signal generated based on the spinning of the multi-nucleus of the object. The controller or console may further reconstruct the second magnetic resonance signal based on the spinning of the multi-nucleus of the object and generate a multi-nucleus image based on the reconstructed magnetic resonance signal.

Consistent with the present disclosure, the controller of the MRI system may perform method 300, method 400, method 500, method 600, or method 800 using the scanner and the at least one multi-nucleus coil.

In some embodiments, the MRI system may further include a display (e.g., display 208). The display may include a display interface (e.g., user interface) that displays the generated hydrogen nucleus image. The user interface may further display at least one coil identification of the at least one multi-nucleus coil on the hydrogen nucleus image. Consistent with some embodiments, a bounding box may be displayed within a range (e.g., imaging range) defined by the at least one coil identification of the at least one multi-nucleus coil. The bounding box indicates the location of the ROI of the object. Displaying the coil identification and the bounding box corresponding to the ROI in the user interface may facilitate the user to determine whether the ROI is within the imaging range of the at least one multi-nucleus coil, and thereby improve the quality of the multi-nucleus imaging.

In some embodiments, the user may be able to adjust the bounding box displayed in the user interface. In response to the adjustment of the bounding box, parameter values (e.g., positioning parameter) in the scanning protocol corresponding to the multi-nucleus coil may be updated automatically. For example, after reviewing the ROI on the hydrogen nucleus image, if the user determines that the bounding box does not accurately indicate the location of the ROI, the user may therefore adjust the position or size of the bounding box on the displayed hydrogen nucleus image. The positioning parameters in the scanning protocol corresponding to the multi-nucleus coil thereby may be updated accordingly.

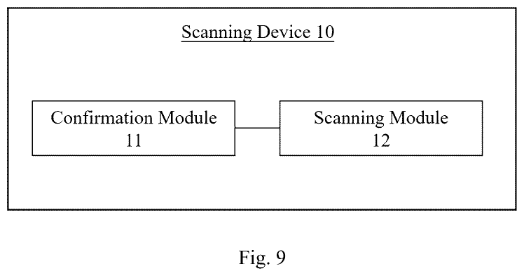

FIG. 9 is a schematic diagram showing an exemplary scanning device (referred as “scanning device 10” hereafter) for performing a scanning method, according to some embodiments of the present disclosure. For example, scanning device 10 may perform method 300, method 400, method 500, method 600, or method 800. As shown in FIG. 9, scanning device 10 may include confirmation module 11 and scanning module 12.

In some embodiments, confirmation module 11 may use an RF coil of an MRI system to scan an object, generate a hydrogen nucleus image of the object, and identify a coil identification of a multi-nucleus coil in the hydrogen nucleus image. Confirmation module 11 may further determine an imaging range of the multi-nucleus coil based on the identified coil identification in the hydrogen nucleus image. Scanning module 12 may control the multi-nucleus coil to scan the object based on the determined imaging range of the multi-nucleus coil and generate a multi-nucleus image of the object.

In some embodiments, scanning module 12 may include a display subunit, a rendering subunit, and a scanning subunit (not shown in FIG. 9). The display subunit may display the hydrogen nucleus image on a display interface. The hydrogen nucleus image includes a ROI of the object. The rendering subunit may render an imaging range of the multi-nucleus coil and the ROI of the object each in a respective color on the hydrogen nucleus image. The scanning subunit may control the multi-nucleus coil to scan the object and generate the multi-nucleus image of the object according to the rendered imaging range and ROI.

Consistent with the present disclosure, in response to a first operation by a user of scanning device 10 on the rendered imaging range and the rendered ROI, the scanning subunit may use the multi-nucleus coil to scan the object and generate the multi-nucleus image of the object based on the multi-nucleus coil and the ROI. Consistent with the present disclosure, the first operation indicates that the render ROI is within the imaging range of the multi-nucleus coil.

In some embodiments, in response to the first operation on the rendered imaging range and the rendered ROI, the scanning subunit may further determine a scanning protocol corresponding to the multi-nucleus coil. The MRI system may scan the object using the multi-nucleus coil according to the scanning protocol and generate the multi-nucleus image of the object.

In some embodiments, in response to a second operation on the rendered imaging range and the rendered ROI, the scanning subunit may confirm adjustment to positions of the RF coil and the multi-nucleus coil relative to the object, and perform step S510 or step S810 to rescan the object using the RF coil. Consistent with some embodiments, the second operation indicates that the render ROI is not within the imaging range of the multi-nucleus coil.

In some embodiments, confirmation module 11 may scan the object using the RF coil and generate multiple hydrogen nucleus images of different scanning sections. Confirmation module 11 may further reconstruct at least one coil identification in the hydrogen nucleus images of the different scanning sections and generate at least one 3-dimensional coil identification of the at least one multi-nucleus coil.

In some embodiments, each module (e.g., confirmation module 11, scanning module 12, or the subunits) in scanning device 10 may be implemented in whole or in part by software, hardware, or a combination thereof. Each module may be embedded in or independent of a processor in a computer device in the form of hardware, or may be stored in a memory in a computer device in the form of software, so that the processor may perform operations corresponding to each module.

According to some embodiments of the present disclosure, a computer device may be provided. FIG. 2 shows an exemplary computer device, according to embodiments of the present disclosure. Consistent with some embodiments, the computer device (e.g., computer device 102) may include a processor (e.g., processor 202) and a memory (e.g., memory 204). Memory 204 may have a computer program stored therein. Processor 202 may execute the computer program to perform the various operations. The operations may include scanning an object using an RF coil of a magnetic resonance device (e.g., magnetic resonance device 104), generating at least one hydrogen nucleus image of the object, and identifying at least one coil identification of at least one multi-nucleus coil in the hydrogen nucleus image, the at least one multi-nucleus coil being placed on the body surface of the object. The operations may further include determining an imaging range of the at least one multi-nucleus coil based on the at least one identified coil identification in the hydrogen nucleus image. The operations may also include scanning multi-nucleus of the object using the magnetic resonance device based on the imaging range of the at least one multi-nucleus coil of the magnetic resonance device, and generating a multi-nucleus image of the object.

In some embodiments, processor 202 may further display the hydrogen nucleus image including a ROI of the object on a display interface (e.g., display 208). Processor 202 may also render the imaging range of the multi-nucleus coil and the ROI of the object on the hydrogen nucleus image in different colors. Processor 202 may additionally use the multi-nucleus coil to scan the object and generate the multi-nucleus image of the object according to the rendered imaging range and the rendered ROI.

Consistent with some embodiments, in response to the first operation from the user on the rendered imaging range and the rendered ROI, processor 202 may use the multi-nucleus coil to scan the object and generate the multi-nucleus image of the object based on the rendered multi-nucleus coil and the rendered ROI. Consistent with the present disclosure, the first operation indicates to the computer device that the render ROI is within the imaging range of the multi-nucleus coil

In some embodiments, in response to the first operation on the rendered imaging range and the rendered ROI, processor 202 may further determine a scanning protocol corresponding to the multi-nucleus coil based on the rendered imaging range and the rendered ROI. Processor 202 may control magnetic resonance device 104 to scan the object using the multi-nucleus coil according to the scanning protocol and generate the multi-nucleus image of the object.

Consistent with the present disclosure, in response to a second operation on the rendered imaging range and the rendered ROI, processor 202 may confirm the adjustment of positions of the RF coil or the multi-nucleus coil relative to the object, and perform step S510 or step S810 to rescan the object using the RF coil and generate a new hydrogen nucleus image. Consistent with some embodiments, the second operation indicates that the render ROI is not within the imaging range of the multi-nucleus coil.

Consistent with some embodiments, processor 202 may also scan the object using the RF coil and generate multiple hydrogen nucleus images in different scanning sections. Processor 202 may additionally reconstruct at least one coil identification imaged in the hydrogen nucleus images of the different scanning sections to generate at least one 3-dimensional coil identification of the at least one multi-nucleus coil.

According to some embodiments of the present disclosure, a non-transitory computer readable storage medium may be provided. For example, the non-transitory computer readable storage medium (e.g., non-volatile storage medium 216 in FIG. 2) may have a computer program (e.g., computer program 220 in FIG. 2) stored thereon. A processor (e.g., processor 202 in FIG. 2) may execute the computer program (e.g., computer program 220) to perform the following operations:
scanning an object using an RF coil of an magnetic resonance device (e.g., magnetic resonance device 104), generating at least one hydrogen nucleus image of the object, and identifying at least one coil identification of at least one multi-nucleus coil in the hydrogen nucleus image, the at least one multi-nucleus coil being placed on the body surface of the object;
determining an imaging range of the at least one multi-nucleus coil based on the at least one identified coil identification in the hydrogen nucleus image; and
scanning multi-nucleus of the object using the multi-nucleus coil of the magnetic resonance device based on the imaging range of the at least one multi-nucleus coil, and generating a multi-nucleus image of the object.

In some embodiments, processor 202 may further execute computer program 220 to display the hydrogen nucleus image including a ROI of the object on a display interface (e.g., display 208). Processor 202 may also execute computer program 220 to render the imaging range of the multi-nucleus coil and the ROI of the object on the hydrogen nucleus image using different colors. Processor 202 may additionally execute computer program 220 to use the multi-nucleus coil to scan multi-nucleus of the object and generate the multi-nucleus image of the object according to the rendered imaging range and the rendered ROI.

Consistent with some embodiments, in response to a first operation input by the user of the processor on the rendered imaging range and the rendered ROI displayed on the display interface, processor 202 may execute computer program 220 to use the multi-nucleus coil to scan the object and generate the multi-nucleus image of the object based on the rendered multi-nucleus coil and the rendered ROI. Consistent with the present disclosure, the first operation may indicates that the rendered ROI is within the imaging range of the multi-nucleus coil.

In some embodiments, in response to the first operation on the rendered imaging range and the rendered ROI, processor 202 may further execute computer program 220 to determine a scanning protocol corresponding to the multi-nucleus coil based on the rendered imaging range and the rendered ROI. Processor 202 may further control magnetic resonance device 104 to scan the object using the multi-nucleus coil according to the scanning protocol and generate the multi-nucleus image of the object.

Consistent with the present disclosure, in response to a second operation on the rendered imaging range and the rendered ROI, processor 202 may execute computer program 220 to confirm the adjustment of positions of the RF coil or the multi-nucleus coil relative to the object, and perform scanning the object using the RF coil of magnetic resonance device 104 (e.g., step S510 or step S810). Consistent with some embodiments, the second operation indicates that the render ROI is not within the imaging range of the multi-nucleus coil.

Consistent with some embodiments, processor 202 may also execute computer program 220 to scan the object using the RF coil of magnetic resonance device 104 and generate multiple hydrogen nucleus images of different scanning sections. Processor 202 may additionally execute computer program 220 to reconstruct at least one coil identification imaged in the hydrogen nucleus images of the different scanning sections and generate at least one 3-dimensional coil identification of the at least one multi-nucleus coil.

A person of ordinary skill in the art may understand that all or part of the processes in the above-mentioned embodiments can be performed by a hardware executed through a computer program, and the computer program may be stored on a non-volatile computer-readable storage medium or a memory. When the computer program is executed by the hardware, the computer program may cause the hardware to perform the embodiments of the above-mentioned methods. Memory or other medium provided in the present disclosure may include at least one non-volatile or volatile memory. The non-volatile memory may include Read-Only Memory (ROM), magnetic tape, floppy disk, flash memory, optical memory, high-density embedded non-volatile memory, Resistive Random Access Memory (ReRAM), Magnetoresistive Random Access Memory (MRAM), Ferroelectric Random Access Memory (FRAM), Phase Change Memory (PCM), graphene memory, etc. The volatile memory may include Random Access Memory (RAM) or external cache memory, etc. RAM may include Static Random Access Memory (SRAM) or Dynamic Random Access Memory (DRAM). Processors that provided in the present disclosure may be a general-purpose processor, a central processing unit, a graphics processor, a digital signal processor, a programmable logic device, or a data processing logic device based on quantum computing, but are not limited to these types.

It will be apparent to those skilled in the art that various modifications and variations can be made to the disclosed system and related methods. Other embodiments will be apparent to those skilled in the art from consideration of the specification and practice of the disclosed system and related methods.

It is intended that the specification and examples be considered as exemplary only, with a true scope being indicated by the following claims and their equivalents.

What is claimed is:

1. A Magnetic Resonance Imaging (MRI) scan method, comprising:
generating a first hydrogen nucleus image of an object using a Radio Frequency (RF) coil of the MRI system;
identifying at least one coil identification of at least one multi-nucleus coil in the first hydrogen nucleus image, wherein the at least one multi-nucleus coil is placed on surface of the object;
determining an imaging range of the at least one multi-nucleus coil based on the at least one identified coil identification in the first hydrogen nucleus image; and
determining whether to generate a multi-nucleus image of the object using the at least one multi-nucleus coil based on the imaging range of the at least one multi-nucleus coil and a Region Of Interest (ROI) of the object on the first hydrogen nucleus image.

2. The MRI scan method according to claim 1, wherein determining whether to generate the multi-nucleus image of the object using the at least one multi-nucleus coil based on the imaging range of the at least one multi-nucleus coil and the ROI comprises:
rendering the imaging range and the ROI, respectively, on the first hydrogen nucleus image; and
determining whether to generate the multi-nucleus image of the object using the at least one multi-nucleus coil based on whether the rendered ROI is within the rendered imaging range of the at least one multi-nucleus coil.

3. The MRI scan method according to claim 2, wherein determining whether to generate the multi-nucleus image of the object using the at least one multi-nucleus coil based on whether the rendered ROI is within the rendered imaging range of the at least one multi-nucleus coil comprises:
receiving a first operation from a user of the MRI system for the rendered imaging range of the at least one multi-nucleus coil and the rendered ROI, wherein the first operation indicates that the rendered ROI is within the rendered imaging range of the at least one multi-nucleus coil, and
in response to the first operation, generating the multi-nucleus image of the object using the at least one multi-nucleus coil.

4. The MRI scan method according to claim 3, wherein in response to the first operation, generating the multi-nucleus image of the object using the at least one multi-nucleus coil comprises:
in response to the first operation, determining a scanning protocol corresponding to the at least one multi-nucleus oil based on the rendered imaging range of the at least one multi-nucleus coil and the rendered ROI, and
generating the multi-nucleus image of the object using the at least one multi-nucleus coil based on the determined scanning protocol.

5. The MRI scan method according to claim 2, wherein determining whether to generate the multi-nucleus image of the object using the at least one multi-nucleus coil based on whether the rendered ROI is within the rendered imaging range of the at least one multi-nucleus coil comprises:
receiving a second operation from a user of the MRI system for the rendered imaging range of the at least one multi-nucleus coil and the rendered ROI, wherein the second operation indicates that the rendered ROI is not within the rendered imaging range of the at least one multi-nucleus coil; and
in response to the second operation, determining not to generate the multi-nucleus image of the object using the at least one multi-nucleus coil.

6. The MRI scan method according to claim 1, wherein generating the first hydrogen nucleus image of the object using the RF coil of the MRI system comprises:
generating at least one hydrogen nucleus image of each scanning section using the RF coil, and
wherein identifying the at least one coil identification of the at least one multi-nucleus coil on the hydrogen nucleus image comprises:
generating at least one 3-dimensional coil identification of the at least one multi-nucleus coil based on reconstructing at least one coil identification in the at least one hydrogen nucleus image of the different scanning sections.

7. The MRI scan method according to claim 6, wherein the different scanning sections comprise: coronal plane, median sagittal section, or transverse section.

8. The MRI scan method according to claim 4, wherein a bounding box is used to indicate the rendered ROI on the first hydrogen nucleus image displayed on the user interface, wherein the bounding box is located within the rendered imaging range of the at least one multi-nucleus coil.

9. The MRI scan method according to claim 8, wherein when the bounding box is adjusted by a user of the MRI system, a positioning parameter of the scanning protocol corresponding to the at least one multi-nucleus coil updates according to the adjustment of the bounding box.

10. The MRI scan method according to claim 5, wherein determining not to generate the multi-nucleus image of the object using the at least one multi-nucleus coil comprises:
determining an updated position of the RF coil of the MRI system or an updated position of the at least one multi-nucleus coil for generating a second hydrogen nucleus image of the object based on the position-updated RF coil or the at least one position-updated multi-nucleus coil.

11. A Magnetic Resonance Imaging (MRI) system, comprising:
a scanner, comprising a Radio Frequency (RF) coil, wherein the scanner has an imaging area to accommodate an object;
at least one multi-nucleus coil placed on body surface of the object; and
a controller configured to:
control the RF coil to acquire MR signals of hydrogen nucleus species,
reconstruct a first hydrogen nucleus image from the MR signals of hydrogen nucleus species,
identify at least one coil identification of the at least one multi-nucleus coil in the first hydrogen nucleus image,
determine an imaging range of the at least one multi-nucleus coil based on the at least one identified coil identification in the first hydrogen nucleus image, and
determine, by a user of the MRI system, whether to generate a multi-nucleus image of the object using the at least one multi-nucleus coil based on the imaging range of the at least one multi-nucleus coil and a Region Of Interest (ROI) of the object on the first hydrogen nucleus image.

12. The MRI system according to claim 11, further comprising:
a display, displaying a user interface, wherein the user interface displays the at least one coil identification of the at least one multi-nucleus coil, wherein a bounding box is displayed within a range determined based on the at least one coil identification of the at least one multi-nucleus coil, wherein the bounding box indicates a location of the ROI on the first hydrogen nucleus image.

13. The MRI system according to claim 11, wherein the RF coil is configured to:
produce an excitation pulse, wherein the excitation pulse is used for exciting proton nucleus of the object to spin; and
receive a magnetic resonance signal generated based on the spinning of the proton nucleus of the object.

14. The MRI system according to claim 11, wherein to determine whether to generate the multi-nucleus image of the object using the at least one multi-nucleus coil based on the imaging range of the at least one multi-nucleus coil and the ROI, the controller is further configured to:
render the imaging range and the ROI, respectively, on the first hydrogen nucleus image; and
determine whether to generate the multi-nucleus image of the object using the at least one multi-nucleus coil based on whether the rendered ROI is within the rendered imaging range of the at least one multi-nucleus coil.

15. The MRI system according to claim 14, wherein to determine whether to generate the multi-nucleus image of the object using the at least one multi-nucleus coil based on whether the rendered ROI is within the rendered imaging range of the at least one multi-nucleus coil, the controller is further configured to:
receive a first operation from the user of the MRI system for the rendered imaging range of the at least one multi-nucleus coil and the rendered ROI, wherein the first operation indicates that the rendered ROI is within the rendered imaging range of the at least one multi-nucleus coil, and
in response to the first operation, generate the multi-nucleus image of the object using the at least one multi-nucleus coil.

16. The MRI system according to claim 15, wherein to generate the multi-nucleus image of the object using the at least one multi-nucleus coil, the controller is further configured to:
in response to the first operation, determine a scanning protocol corresponding to the at least one multi-nucleus coil based on the rendered imaging range of the at least one multi-nucleus coil and the rendered ROI, and
generate the multi-nucleus image of the object using the at least one multi-nucleus coil based on the determined scanning protocol.

17. The MRI system according to claim 14, wherein to determine whether to generate the multi-nucleus image of the object using the at least one multi-nucleus coil based on whether the rendered ROI is within the rendered imaging range of the at least one multi-nucleus coil, the controller is further configured to:
receive a second operation from the user of the MRI system for the rendered imaging range of the at least one multi-nucleus coil and the rendered ROI, wherein the second operation indicates that the rendered ROI is not within the rendered imaging range of the at least one multi-nucleus coil; and
in response to the second operation, determine not to generate the multi-nucleus image of the object using the at least one multi-nucleus coil.

18. The MRI system according to claim 11, wherein to generate the first hydrogen nucleus image of the object using the RF coil of the MRI system, the controller is further configured to:
generate at least one hydrogen nucleus image of each scanning section using the RF coil, and
wherein to identify the at least one coil identification of the at least one multi-nucleus coil in the hydrogen nucleus image, the controller is further configured to:
generate at least one 3-dimensional coil identification of the at least one multi-nucleus coil based on reconstructing at least one coil identification in at least one hydrogen nucleus image of different scanning sections.

19. The MRI system according to claim 18, wherein the different scanning sections comprise:
coronal plane, median sagittal section, or transverse section.

20. A device, comprising a processor; and a memory having a computer program stored thereon, wherein the computer program, when executed by the processor, causes the processor to perform operations comprising:
generating a first hydrogen nucleus image of an object using a Radio Frequency RF coil of a Magnetic Resonance Imaging (MRI) system,
identifying at least one coil identification of at least one multi-nucleus coil in the first hydrogen nucleus image, wherein the at least one multi-nucleus coil is placed on body surface of the object;
determining an imaging range of the at least one multi-nucleus coil based on the at least one identified coil identification on the first hydrogen nucleus image; and
determining whether to generate a multi-nucleus image of the object using the at least one multi-nucleus coil based on the imaging range of the at least one multi-nucleus coil and a Region Of Interest (ROI) of the object on the first hydrogen nucleus image.
